(19) United States
(12) Patent Application Publication
(10) Pub. No.: US 2021/0143003 A1
(43) Pub. Date: May 13, 2021

(54) METHOD OF FORMING A STRUCTURE INCLUDING SILICON OXIDE

(71) Applicant: ASM IP Holding B.V., Almere (NL)

(72) Inventors: Hideaki Fukuda, Tokyo (JP); Shinya Ueda, Tokyo (JP); Kazuhiro Kimura, Tokyo (JP)

(21) Appl. No.: 17/093,564

(22) Filed: Nov. 9, 2020

Related U.S. Application Data
(60) Provisional application No. 62/933,693, filed on Nov. 11, 2019.

(51) Int. Cl. H01L 21/02; C23C 16/40; C23C 16/455

(52) U.S. Cl. CPC H01L 21/0228; C23C 16/45538; C23C 16/45553; C23C 16/401

(57) ABSTRACT

Methods for depositing on a surface of a substrate are disclosed. Exemplary methods include depositing a silicon oxide material using a cyclical deposition process, and reflowing the material during one or more of the step of depositing and a post-deposition anneal step. Structures including a layer of the material are also disclosed.

### CROSS-REFERENCE TO RELATED APPLICATIONS

This application claims the benefit of U.S. Provisional Application No. 62/933,693, filed on Nov. 11, 2019, in the United States Patent and Trademark Office, the disclosure of which is incorporated herein in its entirety by reference.

### FIELD OF INVENTION

The present disclosure generally relates to methods of forming structures suitable for use in the manufacture of electronic devices. More particularly, examples of the disclosure relate to methods that include formation of silicon oxide layers.

### BACKGROUND OF THE DISCLOSURE

During the manufacture of devices, such as semiconductor devices, it is often desirable to fill features (e.g., trenches or gaps) on the surface of a substrate with insulating or dielectric material. Some techniques to fill features include the deposition and reflow of borophosphosilicate glass (BPSG).

Use of BPSG in the manufacture of electronic devices has been reported since the 1970s. BPSG films can be deposited using one of several chemical vapor deposition (CVD) techniques, such as atmospheric-pressure CVD (APCVD), reduced-pressure CVD (RPCVD), low-pressure CVD (LPCVD), plasma-enhanced CVD (PECVD), and the like. Once deposited, the BPSG films can be reflowed—e.g., at temperatures of about 700° C.-1000° C.—to, for example, fill the gaps or trenches.

Although such techniques can work well for several applications, filling features using traditional BPSG CVD deposition techniques has several shortcomings, particularly, as the size of the features to be filled decreases. For example, CVD-deposited BPSG exhibits relatively poor step coverage, and thus voids can form within the deposited material. Such voids can remain after reflowing the deposited material. In addition, relatively high temperatures and long annealing times are used to reflow the BPSG material in an effort to reduce voids. Further, the relatively high film growth rate of CVD-deposited BPSG makes BPSG generally unsuitable for filling gaps of nm-order three-dimensional patterns. Additionally, under-layer damage and diffusion of B and P from the BPSG material to an under layer can result using some CVD deposition techniques.

As device and feature sizes continue to decrease, it becomes increasingly difficult to apply the conventional BPSG deposition and reflow techniques to manufacturing processes. Accordingly, improved methods for forming structures, particularly, for methods of filling gaps during the formation of a structure, are desired.

Any discussion, including discussion of problems and solutions, set forth in this section has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming structures suitable for use in the formation of devices. While the ways in which various embodiments of the present disclosure address drawbacks of prior methods and structures are discussed in more detail below, in general, exemplary embodiments of the disclosure provide improved methods for filling features on a surface of a substrate and/or to forming layers or films comprising silicon and oxygen, such as films comprising silicon, oxygen, and one or more of boron, phosphorous, and germanium.

In accordance with at least one embodiment of the disclosure, a method for depositing material within one or more features on a substrate surface includes providing a substrate comprising the one or more features into a reaction chamber, depositing a material, wherein a chemical formula of the material comprises Si and O onto the one or more features using a cyclical deposition process, and reflowing the material during one or more of the step of depositing and a post-deposition anneal step. The chemical formula further comprises one or more of B, P, Ge, Na, C, Al, Mg, Ca, Sr, and/or Ba. The cyclical deposition process can include a plasma-enhanced cyclical deposition process, such as a plasma-enhanced atomic layer deposition (PEALD) processor a hybrid PEALD-plasma enhanced chemical vapor deposition (PECVD) process. A temperature within the reaction chamber during the step of reflowing can be less than 700° C. or between about 400° C. and about 700° C., for example, between about 450° C. and about 600° C. The step of reflowing can be performed in an atmosphere comprising an inert gas, such as an atmosphere consisting of the inert gas or comprising the inert gas and another gas, such as an oxidant (e.g., oxygen). A pressure within the reaction chamber during the step of reflowing (e.g., in the atmosphere comprising an oxidant and/or an inert gas) can be about 0.1 Pa to about atmospheric pressure. The method can include a step of depositing a layer of silicon oxide (SiOₓ) prior to the step of depositing the material and/or a step of depositing a layer of silicon oxide (SiOₓ) after the step of depositing the material. Additionally or alternatively, the method can include a step of depositing a silicon nitride (SiₓN_{y}) layer prior to the step of depositing the material and/or a step of depositing a silicon nitride (SiₓN_{y}) layer after the step of depositing the material.

In accordance with at least one other embodiment of the disclosure, a method of forming a structure includes providing a substrate into a reaction chamber and depositing a material, wherein a chemical formula of the material comprises B, Si, and O, onto the substrate using a cyclical deposition process. The method can further include a step of annealing. The step of annealing can be performed in an atmosphere, at a pressure, and/or at a temperature as noted above or elsewhere herein.

In accordance with yet further exemplary embodiments of the disclosure, a structure is formed, at least in part, according to a method described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a structure including a void formed within material deposited within a feature.

FIG. 2 illustrates a structure in accordance with at least one embodiment of the disclosure.

FIG. 3 illustrates a method in accordance with at least one embodiment of the disclosure.

FIG. 4 illustrates additional structures in accordance with at least one embodiment of the disclosure.

FIG. 5 and FIG. 6 illustrate scanning transmission electron microscopy images of structures formed in accordance with at least one embodiment of the disclosure.

alt will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of depositing materials, to methods of forming structures, and to structures formed using the methods. Byway of examples, the methods described herein can be used to fill features, such as gaps (e.g., trenches or vias) on a surface of a substrate with material, such as insulating (e.g., dielectric) material. By way of particular examples, a chemical formula of the material can include Si and O. As set forth in more detail below, the chemical formula can additionally include one or more (e.g., two or more, three or more, or the like) of nitrogen, boron, phosphorous, germanium, sodium, carbon, aluminum, magnesium, calcium, strontium, and/or barium.

In this disclosure, “gas” can refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, which includes a seal gas, such as a rare gas. In some cases, such as in the context of deposition of material, the term “precursor” can refer to a compound that participates in the chemical reaction that produces another compound, and particularly to a compound that constitutes a film matrix or a main skeleton of a film, whereas the term “reactant” can refer to a compound, in some cases other than precursors, that activates a precursor, modifies a precursor, or catalyzes a reaction of a precursor; a reactant may provide an element (such as O, N, C) to a film matrix and become a part of the film matrix when, for example, radio frequency (RF) power is applied. In some cases, the terms precursor and reactant can be used interchangeably. The term “inert gas” refers to a gas that does not take part in a chemical reaction to an appreciable extent and/or a gas that excites a precursor when RF power is applied, but unlike a reactant, it may not become a part of a film matrix to an appreciable extent.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as gaps, recesses, vias, lines, and the like formed within or on at least a portion of a layer or bulk material of the substrate. By way of examples, one or more features can have a width of about 10 nm to about 100 nm, a depth or height of about 30 nm to about 1000 nm, and/or an aspect ratio of about 3 to 100 or about 3 to about 20.

In some embodiments, “film” refers to a layer extending in a direction perpendicular to a thickness direction. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous- or not.

As used herein, the term “layer comprising silicon and oxygen” or “silicon oxide layer” can refer to a layer whose chemical formula can be represented as including silicon and oxygen. Layers comprising silicon oxide can include other elements, such as one or more of nitrogen, boron, phosphorous, germanium, sodium, carbon, aluminum, magnesium, calcium, strontium, and/or barium.

As used herein, the term “structure” can refer to a partially or completely fabricated device structure. By way of examples, a structure can include a substrate with one or more layers and/or features formed thereon.

As used herein, the term “cyclic deposition process” can refer to a vapor deposition process in which deposition cycles, typically a plurality of consecutive deposition cycles, are conducted in a process chamber. Cyclic deposition processes can include cyclic chemical vapor deposition (CVD) and atomic layer deposition processes. A cyclic deposition process can include one or more cycles that include plasma activation of a precursor, a reactant, and/or an inert gas.

As used herein, the term “atomic layer deposition” (ALD) can refer to a vapor deposition process in which deposition cycles, typically a plurality of consecutive deposition cycles, are conducted in a process chamber. Typically, during each cycle, the precursor is chemisorbed to a deposition surface (e.g., a substrate surface or a previously-deposited underlying surface such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove any excess precursor from the process chamber and/or remove any excess reactant and/or reaction byproducts from the process chamber after conversion of the chemisorbed precursor. Further, the term “atomic layer deposition,” as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas. Plasma-enhanced ALD (PEALD) can refer to an ALD process, in which a plasma is applied during one or more of the ALD steps.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

Turning now to the figures, FIG. 1 illustrates a structure 100. Structure 100 includes a substrate 102 and a silicon oxide (e.g., a borophosphosilicate glass) film 104. Substrate 102 includes a feature (e.g., a trench or via) 106. As illustrated, silicon oxide film 104 includes a void 108. Void 108 may form when the silicon oxide film is deposited in a non-conformal manner—e.g., using traditional CVD techniques. High-temperature annealing can be used to remove or reduce a size of void 108. However, such high-temperature processes may be undesirable for many applications. Structure 100 also includes underlayer damaged area 110. Underlayer damaged area 110 can include damage to a substrate or to another layer—e.g., a thin previously-deposited silicon oxide or silicon nitride layer. Underlayer damaged area 110 can result from a high-power plasma process that can be used to deposit the silicon oxide layer.

FIG. 2 illustrates a structure 200 in accordance with exemplary embodiments of the disclosure. Structure 200 includes a substrate 202 and a silicon oxide layer 204. Structure 200 can also include a (e.g., an oxide, nitride, or oxynitride, such as silicon oxide, silicon nitride, or silicon oxynitride) layer 206 underneath silicon oxide layer 204 and/or a layer 208 (e.g., an oxide, nitride, or oxynitride, such as silicon oxide, silicon nitride, or silicon oxynitride) overlying silicon oxide layer 204.

Substrate 202 can be the same or similar to substrate 102. Silicon oxide layer 204 can be formed according to a method as described herein. As illustrated, silicon oxide layer 204 does not include a seam or a void. And, structure 200 includes relatively little to no damage to an underlying surface—e.g., little to no underlayer damaged area.

In addition to silicon and oxygen, silicon oxide layer 204 can include one or more of nitrogen, boron, phosphorous, germanium, sodium, carbon, aluminum, magnesium, calcium, strontium, and/or barium, and particularly one or more of B, P, and Ge. By way of examples, silicon oxide layer 204 can be or include borophosphosilicate glass (BPSG).

FIG. 3 illustrates a method (e.g., a method for depositing material and/or a method of forming a structure) in accordance with exemplary embodiments of the disclosure. Method 300 includes the steps of providing a substrate (step 302), depositing a material (step 304), and reflowing the material (step 306).

During step 302, a substrate is provided into a reaction chamber of a reactor. In accordance with examples of the disclosure, the reaction chamber can form part of cyclical deposition reactor, such as an atomic layer deposition (ALD) reactor. Exemplary single substrate reactors, suitable for use with method 300, include reactors designed specifically to perform ALD processes. Exemplary suitable batch ALD reactors can process multiple substrates at one time. Various steps of method 300 can be performed within a single reaction chamber or can be performed in multiple reaction chambers, such as reaction chambers of a clustertool. Optionally, a reactor including the reaction chamber can be provided with a heater to activate the reactions by elevating the temperature of one or more of the substrate and/or the reactants/precursors.

During step 302, a substrate can be brought to a desired temperature and/or the reaction chamber can be brought to a desired pressure, such as a temperature and/or pressure suitable during step 304. By way of examples, a temperature (e.g., of a substrate or a substrate support) within a reaction chamber can be between about room temperature and about 600° C., or about 300° C. and about 500° C. A pressure within the reaction chamber can be about 1 torr to about 30 torr or about 3 torr to about 7 torr.

During step 304, a silicon oxide layer is deposited on the substrate. Exemplary techniques for depositing the silicon oxide layer on the substrate surface include a cyclical deposition process, such as an ALD process. In some embodiments, step 304 includes depositing the layer of material on the substrate/feature using a cyclic deposition process, such as a cyclic CVD or an ALD process. By way of particular example, the layer of material can be deposited using PEALD.

An exemplary cyclic or PEALD process can include the sub steps of exposing the substrate to a silicon precursor, purging the reaction chamber, expositing the substrate to a reactant (e.g., a plasma-activated reactant), purging the reaction chamber, and repeating these steps until an initial desired thickness of the silicon oxide layer is obtained. A temperature within the reaction chamber and/or of a susceptor can be the same or similar as the temperature during step 302. Similarly, the pressure within the reaction chamber can be as described above in connection with step 302.

Exposing the substrate to a silicon precursor can include providing a silicon precursor selected from the group consisting of one or more of (dimethylamino)silane(DMAS), bis(dimethylamino)silane (BDMAS), bis(diethylamino)silane (BDEAS), bis(ethylmethylamino)silane (BEMAS), bis(tertbutylamino)silane (BTBAS), tris(dimethylamino)silane (TDMAS), tetrakis(dimethylamino)silane (TKDMAS), tetra(ethoxy)silane(TEOS), tris(tert-butoxy)silanol(TBOS), tris(tert-pentoxy)silanol(TPSOL), and Si(CH3)2(OCH3)2, SiH(CH3)3, Si(CH3)4 to the reaction chamber. A flowrate of the silicon precursor from a silicon precursor source to the reaction chamber can be about 1E-5 mol/sec to about 5E-4 mol/sec, about 1E-4 mol/sec to about 2E-4 mol/sec, or about 1.0E-4 mol/sec to about 1.5E-4 mol/sec. A duration of each exposing the substrate to a silicon precursor sub step can be about 0.05 sec to about 10 sec, about 0.1 sec to about 5 sec, or about 0.1 sec to about 1 sec.

The steps of purging the reaction chamber can include flowing an inert gas to the reaction chamber and/or providing a vacuum pressure within the reaction chamber. A flowrate of the purge gas to the reaction chamber can be about 0.1 slm to about 30 slm, about 1 slm to about 20 slm, or about 5 slm to about 10 slm. The pressure within the reaction chamber can be the same or similar to the pressure described above in connection with step 302. A duration of each purging sub step can be about 0.1 sec to about 10 sec, about 0.2 sec to about 3 sec, or about 0.2 sec to about 1 sec.

The sub step of expositing the substrate to a reactant can include providing one or more of O₂, O₃, CO₂, and N₂O to the reaction chamber. A flowrate of the reactant from a reactant source to the reaction chamber can be about 1 slm to about 20 slm, about 1 slm to about 10 slm, or about 1 slm to about 3 slm. A duration of each exposing the substrate to a reactant sub step can be about 0.05 sec to about 10 sec, about 0.1 sec to about 5 sec, or about 0.1 sec to about 1 sec. In accordance with exemplary aspects of the disclosure, an activated (e.g., oxygen) species formed by exposing a reactant gas (e.g., an oxygen source gas), such as oxygen, or C₂, N₂O, O₃, for example, to radio frequency and/or microwave plasma. A direct plasma and/or a remote plasma can be used to form the activated species. In some cases, the reactant can be continuously flowed to the reaction chamber and the reactant can be periodically activated for a cyclical deposition process. In these cases, anon time for the plasma for each cycle can be about 0.02 sec to about 10 sec, about 0.1 sec to about 5 sec, or about 0.1 sec to about 1 sec.

The step of repeating (step 308) can be repeated a number of times until a desired film thickness is obtained. Further, each step, sub step, or subsets of sub steps can be repeated prior to proceeding to the next step.

In the case of cyclic CVD, a reactant and a precursor can be introduced into the reaction chamber at the same time. The reactants and/or reaction byproducts can be purged as described herein. Further, hybrid CVD/PECVD-ALD/PEALD process can be used, wherein a reactant and precursor can react in the gas phase for a period of time and wherein some ALD occurs.

During step 304, additional precursors and/or reactants can be provided to the reaction chamber. For example, precursors or reactants comprising one or more of nitrogen, boron, phosphorous, germanium, sodium, carbon, aluminum, magnesium, calcium, strontium, and/or barium can be provided to the reaction chamber during step 304. These additional precursors and/or reactants can be flowed with other precursors or reactants or can be separately flowed to the reaction chamber. Byway of examples, a boron precursor can be flowed to the reaction chamber during step 304. The boron precursor can be selected from, for example, one or more of the group consisting of trimethylborate (TMB) and triethylborate (TEB). Additionally or alternatively, a phosphorous precursor can be provided into the reaction chamber. The phosphorous precursor can be selected from, for example, one or more of the group consisting of trimethylphosphate (TMPO), trimethylphosphite (TMPI), triethylphosphate (TEPO), and triethylphosphite (TEPI). Additionally or alternatively, a germanium precursor can be provided into the reaction chamber. Exemplary germanium precursor include tetrakis(dimethylamino)germanium. Any combination of the above additional precursors and reactants can be provided to the reaction chamber during step 304.

In accordance with some examples of the disclosure, a concentration of one or more of boron, phosphorous, germanium and the like can be tuned by controlling a ratio of number of, for example, feeding times of Si source, B source and P source. For example, when ratio of number of feeding times of Si and B and P is 1:0:0, pure SiOₓ is deposited. The deposited material can be post-annealed at >450° C. under inert atmosphere, and consequently, the film reflows and gap-fill is achieved. Because the eutectic point of B₂O₃—SiO₂ system is 438° C., a post-anneal (reflow) temperature can be >438° C. or >450° C.

Once a desired amount of material is deposited during step 304, the material can be reflowed. Although separately illustrated, step 306 can occur during step 304. If steps 304 and 306 are at least partially separated, steps 304 and 306 can be performed in the same reaction chamber or in a different reaction chamber.

In accordance with various embodiments of the disclosure, a temperature within the reaction chamber during step 306 is less than 700° C. or is between about 400° C. and about 700° C., is less than 600° C. or is between about 400° C. and about 600° C., or is between about 450° C. and about 600° C., or is between about 400° C. and about 650° C. A pressure within the reaction chamber during step 306 can be about 0.1 Pa and about atmospheric pressure, about 1E2 Pa to about 1E5 Pa, or about 1E3 Pa to about 1E5 Pa.

During step 306, an atmosphere in the reaction chamber can include an inert gas. In some cases, the atmosphere can also include an oxidant, such as oxygen. In these cases, the atmosphere can include about 0.1% to about 100%, about 1% to about 100% oxidant in an inert gas. A flowrate of the inert gas can range from about 0.01 slm to about 30 slm, or about 1 slm to about 10 slm. A flowrate of the oxidant during step 306 can range from about 0.01 slm to about 10 slm, about 0.01 slm to about 1 slm.

Although not separately illustrated, method 300 can include one or more of a step of depositing a layer of silicon oxide (SiOₓ) prior to step of depositing the material 304, a step of depositing a layer of silicon oxide (SiOₓ) after step of depositing the material, a step of depositing a silicon nitride (SiₓN_{y}) layer prior to step of depositing the material 304, a step of depositing a silicon nitride (SiₓN_{y}) layer after step of depositing the material, a step of depositing a silicon oxynitride layer prior to step of depositing the material 304, and/or a step of depositing a silicon oxynitride layer after step of depositing the material 304. The oxide, nitride, and/or oxynitride layers can be deposited using a cyclic deposition process, such as an ALD process. Further, when a layer is deposited after step 304, such layer can be deposited before or after step 306.

FIG. 4 illustrates structure 402, 404, which can be formed during steps 304, 306, respectively. Structure 402 includes substrate 406, which can include, for example, any substrate material described herein. Silicon oxide layer 408 is deposited onto substrate 406 using, for example, step 304 of method 300. During one or more of the step of depositing material 304 and reflow material step 306 (e.g., a post-deposition anneal step), silicon oxide layer flows to form flowed silicon oxide layer 410. Steps 304 and 306 can be repeated to fill a feature 412 within substrate 406 and/or until a desired thickness of deposited and flowed material is obtained.

FIGS. 5 and 6 illustrate scanning transmission electron microscopy images of silicon oxide (e.g., BPSG) films deposited onto a patterned substrate. The silicon oxide films were deposited and reflowed according to method 300. As shown, the reflowed material does not include any seams or voids. In the illustrated example, the aspect ratios of the features range from about 3 to about 4 and openings of the features are about 15 nm.

Various examples of the disclosure provide improved methods and structures. Examples of the improvements include:
Because of the relatively low reflow temperatures, exemplary methods can be used in front-end-of-line semiconductor processes. Exemplary methods can deposit high conformality silicon oxide (e.g., BPSG) film on patterned substrate, so that a reduced amount of reflow can be used for gap fill; therefore, post-anneal temperature and time can be greatly reduced.
Because of the initially conformal deposition, void-free gap fill can be achieved on high-AR patterns—e.g., overlying feature having aspect ratios greater than, for example, 2, 5, or between about 3 and about 50.
Corrosion problem of the BPSG gap fill process due to chemically unstable BPSG in the atmosphere can be significantly mitigated or even eliminated.
Structures can include silicon oxide, nitride, and/or oxynitride layers, which can be deposited using a conformal, cyclical process. Therefore, deposition of BPSG can be reduced.
Under-layer damage that can occur during a deposition step can be suppressed. An initial layer of silicon oxide, nitride, and/or oxynitride layer can be deposited on pattern with high conformality by, for example, PEALD; such a layer can suppress plasma damage that might otherwise occur during deposition of BPSG material.
Diffusion of B (and/or other elements) in a silicon oxide layer to an under layer can be reduced.
Distortion of pattern can be suppressed. Stress of BPSG film can be reduced because deposition of BPSG can be minimal, and most parts of the film can be composed by silicon oxide, silicon nitride, or the like. Post-anneal temperature and time can also be reduced and therefore distortion during post-annealing is suppressed.
PEALD and PECVD hybrid process can be performed, which can achieve desired gap fill properties, high run rates, and/or low chemical consumption. For example, PEALD can be used only for a part of the gap fill and other part can be PECVD.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method for depositing material within one or more features on a substrate surface, the method comprising:
providing a substrate comprising the one or more features into a reaction chamber;
depositing a material, wherein a chemical formula of the material comprises silicon and oxygen onto the one or more features using a cyclical deposition process; and
reflowing the material during one or more of the step of depositing and a post-deposition anneal step.

2. The method of claim 1, wherein the cyclical deposition process comprises a plasma-enhanced cyclical deposition process.

3. The method of claim 1, wherein the cyclical deposition process comprises a plasma-enhanced atomic layer deposition (PEALD) process.

4. The method of claim 1, wherein a temperature during the step of reflowing is less than 700° C. or is between about 400° C. and about 700° C.

5. The method of claim 4, wherein the temperature is between about 450° C. and about 600° C.

6. The method of claim 1, wherein an aspect ratio of the features is greater than or equal to 2 or greater than or equal to 5.

7. The method of claim 6, wherein the aspect ratio is between about 3 and about 50.

8. The method of claim 1, wherein the step of reflowing is performed in an atmosphere comprising an inert gas.

9. The method of claim 8, wherein the step of reflowing is performed in an atmosphere comprising an inert gas and an oxidant.

10. The method of claim 1, wherein a pressure within the reaction chamber during the step of reflowing is between about 0.1 Pa and about atmospheric pressure.

11. The method of claim 1, wherein the chemical formula further comprises one or more of B, P, and Ge.

12. The method of claim 11, wherein the material comprises borophosphosilicate glass (BPSG).

13. The method of claim 1, further comprising a step of depositing a layer of silicon oxide (SiOₓ) prior to the step of depositing the material.

14. The method of claim 1, further comprising a step of depositing a layer of silicon oxide (SiOₓ) after the step of depositing the material.

15. The method of claim 1, further comprising a step of depositing a silicon nitride (SiₓN_{y}) layer prior to the step of depositing the material.

16. The method of claim 1, further comprising a step of depositing a silicon nitride (SiₓN_{y}) layer after the step of depositing the material.

17. The method of claim 1, wherein the step of depositing material comprises a hybrid PEALD-plasma enhanced chemical vapor deposition (PECVD) process.

18. The method of claim 1, wherein during the step of depositing the material, a silicon precursor is provided into the reaction chamber.

19. The method of claim 18, wherein the silicon precursor is selected from one or more of the group consisting of (dimethylamino)silane (DMAS), bis(dimethylamino)silane (BDMAS), bis(diethylamino)silane (BDEAS), bis(ethylmethylamino)silane (BEMAS), bis(tertbutylamino)silane (BTBAS), tris(dimethylamino)silane (TDMAS), tetrakis(dimethylamino)silane (TKDMAS), tetra(ethoxy)silane (TEOS), tris(tert-butoxy)silanol (TBOS), tris(tert-pentoxy)silanol (TPSOL), and Si(CH₃)₂(OCH₃)₂, SiH(CH₃)₃, Si(CH₃)₄.

20. The method of claim 1, wherein during the step of depositing the material, a boron precursor is provided into the reaction chamber.

21. The method of claim 20, wherein the boron precursor is selected from one or more of the group consisting of trimethylborate (TMB) and triethylborate (TEB).

22. The method of claim 1, wherein during the step of depositing the material, a phosphorous precursor is provided into the reaction chamber.

23. The method of claim 22, wherein the phosphorous precursor is selected from one or more of the group consisting of trimethylphosphate (TMPO), trimethylphosphite (TMPI), triethylphosphate (TEPO), and triethylphosphite (TEPI).

24. The method of claim 1, wherein during the step of depositing the material, a germanium precursor is provided into the reaction chamber.

25. The method of claim 24, wherein the germanium precursor is selected from the group consisting of tetrakis(dimethylamino)germanium.

26. The method of claim 1, wherein during the step of depositing the material, a reactant is provided.

27. The method of claim 26, wherein reactant active species are formed from the reactant using one or more of a remote plasma and a direct plasma.

28. The method of claim 1, wherein the chemical formula further comprises one or more of nitrogen, boron, phosphorous, germanium, sodium, carbon, aluminum, magnesium, calcium, strontium, and/or barium.

29. A method of forming a structure, the method comprising:
providing a substrate into a reaction chamber; and
depositing a material, wherein a chemical formula of the material comprises B, Si, and O, onto the substrate using a cyclical deposition process.

30. The method of claim 29, further comprising a step of annealing the material at a temperature less than 700° C.

31. A structure formed according to any of the methods of claim 1.
